(19) United States
(12) Patent Application Publication
(10) Pub. No.: US 2025/0192773 A1
(43) Pub. Date: Jun. 12, 2025

(54) GATE DRIVER CIRCUIT, MOTOR DRIVE DEVICE USING SAME, AND ELECTRONIC APPARATUS

(71) Applicant: ROHM CO., LTD., Kyoto (JP)

(72) Inventor: Hiroki SUGAMOTO, Kyoto (JP)

(21) Appl. No.: 18/969,898

(22) Filed: Dec. 5, 2024

(30) Foreign Application Priority Data
Dec. 8, 2023 (JP) 2023-207469

(51) Int. Cl. H03K 17/687; G01R 31/28; H02M 1/08; H02M 7/537

(52) U.S. Cl. CPC H03K 17/6871; G01R 31/2843; H02M 1/08; H02M 7/537; H03K 2217/0063; H03K 2217/0072

(57) ABSTRACT

A gate driver circuit includes: a high-side sensor that asserts a high-side detection signal when a potential difference between two nodes of a high-side transistor constituting an inverter circuit crosses a threshold level; a high-side driver configured to be capable of supplying a high voltage or a low voltage between a gate and a source of the high-side transistor and have a controllable driving capability; and a control circuit that causes the high-side driver to generate the high voltage when a control signal instructs turning-on of the high-side transistor, and changes the driving capability of the high-side driver in response to an assertion of the high-side detection signal, wherein the control circuit determines that abnormality has occurred when the assertion of the high-side detection signal does not occur within a predetermined time.

### CROSS-REFERENCE TO RELATED APPLICATION

The present invention claims priority under 35 U.S.C. § 119 to Japanese Patent Application No. 2023-207469, filed on Dec. 8, 2023, the entire content of which is incorporated herein by reference.

### TECHNICAL FIELD

The present disclosure relates to a gate driver circuit.

### BACKGROUND

A motor driver circuit includes a bridge circuit and a gate driver circuit that drives the bridge circuit. The bridge circuit is a half-bridge circuit, an H-bridge circuit, a three-phase bridge circuit (hereinafter, collectively referred to as a “bridge circuit”), and the like, and includes a high-side transistor and a low-side transistor.

The gate driver circuit includes a high-side driver that drives the high-side transistor, and a low-side driver that drives the low-side transistor. When a gate voltage of the high-side transistor or the low-side transistor is changed rapidly, a through-current or ringing occurs due to a reverse recovery current of a flywheel diode.

In order to suppress the through-current or the ringing, the high-side driver and the low-side driver are configured so that their driving capabilities (current supply capabilities) can be controlled (switched). The gate driver circuit includes a group of sensors that compares a gate-drain voltage and/or a gate-source voltage of each of the high-side transistor and the low-side transistor with a threshold voltage, and in response to a change in an output of the group of sensors, changes the driving capabilities of the high-side transistor and the low-side transistor according to on/off degrees of the high-side transistor and the low-side transistor.

### BRIEF DESCRIPTION OF DRAWINGS

The accompanying drawings, which are incorporated in and constitute a part of the specification, illustrate embodiments of the present disclosure.

FIG. 1 is a circuit diagram of a switching circuit including a gate driver circuit according to an embodiment.

FIG. 2 is a waveform diagram for explaining an operation of the switching circuit of FIG. 1 in a normal state.

FIG. 3 is a waveform diagram for explaining an operation of the switching circuit of FIG. 1 in an abnormal state.

FIG. 4 is a waveform diagram for explaining an operation of the switching circuit of FIG. 1 in a normal state.

FIG. 5 is a waveform diagram for explaining an operation of the switching circuit of FIG. 1 in an abnormal state.

FIG. 6 is a diagram for explaining a modification of abnormality detection in the switching circuit of FIG. 1.

FIG. 7 is a circuit diagram showing an example of a configuration of a high-side sensor.

FIG. 8 is a circuit diagram of a switching circuit including a gate driver circuit according to Modification 1.

FIG. 9 is a circuit diagram of a switching circuit including a gate driver circuit according to Modification 2.

FIG. 10 is a circuit diagram of a motor drive device including a switching circuit according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview of Embodiments

An overview of some exemplary embodiments of the present disclosure will be described. This overview presents, in a simplified form, some concepts of one or more embodiments, as a prologue to the detailed description which is presented later, and for the purpose of basic understanding of the embodiments, but it is not intended to limit the scope of the disclosure. For the sake of convenience, “an embodiment” may be used to refer to one embodiment (example or modification) or a plurality of embodiments (examples or modifications) disclosed herein.

This overview is not a comprehensive overview of all possible embodiments, and it is intended to neither identify key elements of all embodiments nor delineate the scope of some or all aspects. Its sole purpose is to present some concepts of one or more embodiments in a simplified form as a prologue to the more detailed description which is presented later.

A gate driver circuit according to an embodiment includes: a high-side sensor that asserts a high-side detection signal when a potential difference between two nodes of a high-side transistor constituting an inverter circuit crosses a predetermined threshold level; a high-side driver configured to be capable of supplying a high voltage or a low voltage between a gate and a source of the high-side transistor and have a controllable driving capability; and a control circuit that causes the high-side driver to generate the high voltage when a control signal instructs turning on of the high-side transistor, and changes the driving capability of the high-side driver in response to an assertion of the high-side detection signal. The control circuit determines that abnormality has occurred when the assertion of the high-side detection signal does not occur within a predetermined time.

According to this embodiment, a single sensor can be used for both controlling the driving capability of the high-side driver and detecting abnormality, and an abnormality detection function can be added while suppressing an increase in a circuit area.

In one embodiment, the high-side sensor may monitor a drain-source voltage of the high-side transistor.

In one embodiment, the high-side sensor may monitor a gate-source voltage of the high-side transistor.

In one embodiment, the predetermined time may be longer than a turn-on time of the high-side transistor in a normal state.

In one embodiment, the control circuit may determine that abnormality has occurred when the high-side detection signal is negated after being asserted once.

In one embodiment, the gate driver circuit may further include: a low-side sensor that asserts a low-side detection signal when a potential difference between two nodes of a low-side transistor constituting the inverter circuit crosses a predetermined threshold level; and a low-side driver configured to be capable of supplying a high voltage or a low voltage between a gate and a source of the low-side transistor and have a controllable driving capability. The control circuit may cause the low-side driver to generate the high voltage when the control signal instructs turning-on of the low-side transistor, and changes the driving capability of the low-side driver in response to an assertion of the low-side detection signal, and the control circuit may determine that abnormality has occurred when the assertion of the low-side detection signal does not occur within a predetermined time.

In one embodiment, the control circuit may determine that abnormality has occurred when the low-side detection signal is negated after being asserted once.

In one embodiment, the gate driver circuit may be integrally integrated on a single semiconductor substrate.

A motor drive device according to one embodiment includes: an inverter circuit including a high-side transistor and a low-side transistor; and any one of the above-described gate driver circuits, which drives the high-side transistor and the low-side transistor.

An electronic apparatus according to one embodiment includes: a motor; and the above-described motor drive device which drives the motor.

### Embodiments

Some embodiments will be now described with reference to the drawings. Like or equivalent components, members, and processes illustrated in each drawing are given like reference numerals and a repeated description thereof will be appropriately omitted. Further, the embodiments are presented by way of example only and are not intended to limit the present disclosure, and any features or combination thereof described in the embodiments may not necessarily be essential to the present disclosure.

In the present disclosure, “a state where a member A is connected to a member B” includes, in addition to a case where the member A and the member B are physically and directly connected, a case where the member A and the member B are indirectly connected via any other member that does not affect an electrical connection state between the members A and B, or that does not impair functions and effects achieved by combinations of the members A and B.

Similarly, “a state where a member C is installed between a member A and a member B” includes a case where the member A and the member C or the member B and the member C are indirectly connected via any other member that does not affect an electrical connection state between the members A and C or the members B and C, or that does not impair functions and effects achieved by combinations of the members A and C or the members B and C, in addition to a case where the member A and the member C or the member B and the member C are directly connected.

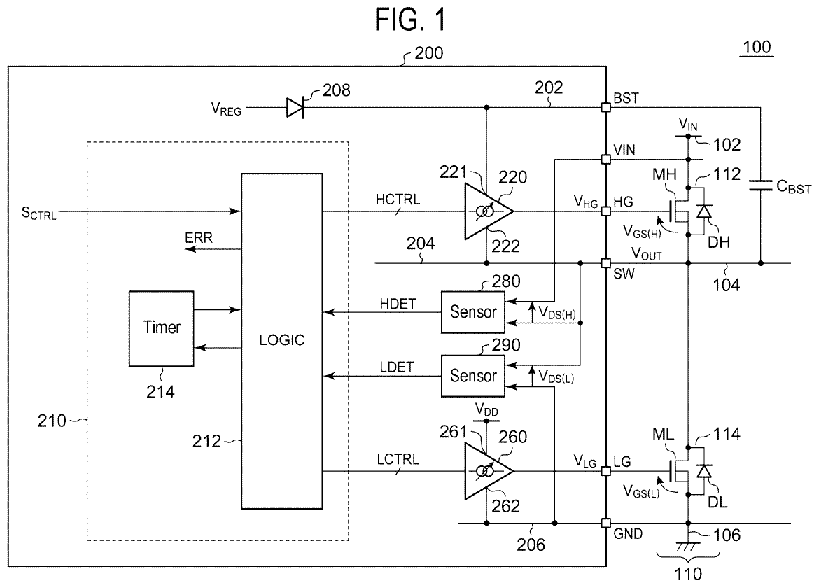

FIG. 1 is a circuit diagram of a switching circuit 100 including a gate driver circuit 200 according to an embodiment. The switching circuit 100 includes a bridge circuit 110 and the gate driver circuit 200. Here, only a configuration of one phase of the switching circuit 100 is shown, but the switching circuit 100 may be a three-phase circuit or an H-bridge circuit.

The bridge circuit 110 includes an upper arm 112 provided between a power supply line (input line) 102 and an output terminal (output line) 104, and a lower arm 114 provided between the output line 104 and a ground line 106. The upper arm 112 includes a high-side transistor MH and a flywheel diode (freewheel diode) DH connected in parallel. The lower arm 114 includes a low-side transistor ML and a flywheel diode DL connected in parallel. In the present embodiment, the high-side transistor MH and the low-side transistor ML are N-channel MOSFETs, and their respective body diodes also function as the flywheel diodes DH and DL. According to applications, a shunt resistor for current detection may be inserted between the low-side transistor ML and the ground line 106.

The gate driver circuit 200 controls the high-side transistor MH and the low-side transistor ML of the bridge circuit 110 based on a control signal S_{CTRL}. The control signal S_{CTRL} can take three states φ1 to φ3.

The first state φ1 is a state that indicates a high output state (V_{OUT}=V_{IN}) in which the high-side transistor MH is turned on and the low-side transistor ML is turned off.

The second state φ2 is a state that indicates a low output state (V_{OUT}=0 V) in which the high-side transistor MH is turned off and the low-side transistor ML is turned on.

The third state φ3 indicates a high impedance state (V_{OUT}=HiZ) in which the high-side transistor MH is turned off and the low-side transistor ML is turned off.

The gate driver circuit 200 is a functional IC, which includes a control circuit 210, a high-side driver 220, a low-side driver 260, a high-side sensor 280, and a low-side sensor 290 and is integrated on a single semiconductor substrate.

A high-side gate pin HG of the gate driver circuit 200 is connected to a gate of the high-side transistor MH, and a low-side gate pin LG of the gate driver circuit 200 is connected to a gate of the low-side transistor ML. A ground pin GND of the gate driver circuit 200 is connected to a source of the low-side transistor ML. A switching pin SW of the gate driver circuit 200 is connected to the output line 104. A bootstrap capacitor C_{BST} is externally attached between a bootstrap pin BST and a switching pin SW of the gate driver circuit 200.

A bootstrap line 202 is connected to the bootstrap pin BST, a switching line 204 is connected to the switching pin SW, and a ground line 206 is connected to the GND pin. A constant voltage V_{REG} is applied to the bootstrap line 202 via a rectifier element 208. The rectifier element 208 and the bootstrap capacitor C_{BST} form a bootstrap circuit, and use a switching operation of the bridge circuit 110 to generate a bootstrap voltage V_{BST}, which is higher by a predetermined voltage ΔV than the voltage (switching voltage) V_{OUT} of the switching line 204, on the bootstrap line 202. When a forward voltage of the rectifier element 208 is Vf, ΔV=V_{REG}−Vf.

The control circuit 210 generates a high-side control signal HCTRL and a low-side control signal LCTRL so that when the control signal S_{CTRL} is in the first state φ1, the high-side transistor MH is turned on and the low-side transistor ML is turned off, when the control signal S_{CTRL} is in the second state φ2, the high-side transistor MH is turned off and the low-side transistor ML is turned on, and when the control signal S_{CTRL} is in the third state φ3, the high-side transistor MH is turned off and the low-side transistor ML is turned off.

The high-side driver 220 controls a gate voltage V_{HG} of the high-side transistor MH in response to the high-side control signal HCTRL. An upper power supply node 221 of the high-side driver 220 is connected to the bootstrap line 202 and the bootstrap voltage V_{BST} is supplied to the upper power supply node 221. A lower power supply node 222 of the high-side driver 220 is connected to the switching line 204 and the switching voltage V_{OUT} is supplied to the lower power supply node 222. The high-side driver 220 generates either the high voltage V_{BST} or the low voltage V_{OUT} at the high-side gate pin HG in response to the high-side control signal HCTRL.

The high-side driver 220 is configured to have a controllable driving capability. The high-side driver 220 is configured as a current-driven or voltage-driven type. In a case of a current-driven type high-side driver, the driving capability of the high-side driver 220 can be recognized as an amount of current sourced to the gate of the high-side transistor MH, or an amount of current sank from the gate of the high-side transistor MH. In a case of a voltage-driven type high-side driver, driving capability of the high-side driver 220 can be recognized as an output impedance. In short, the high-side driver 220 is configured to be capable of switching a slope (slew rate) of the gate voltage V_{HG} generated at the high-side gate pin HG.

The low-side driver 260 controls a gate voltage V_{LG} of the low-side transistor ML in response to the low-side control signal LCTRL. A power supply voltage V_{DD} is supplied to an upper power supply node 261 of the low-side driver 260, and a ground voltage is supplied to a lower power supply node 262 of the low-side driver 260.

Like the high-side driver 220, the low-side driver 260 is configured to have a controllable driving capability and configured to be capable of switching a slope of the gate voltage V_{LG} generated at the low-side gate pin LG.

The high-side sensor 280 compares a voltage between the two nodes of the high-side transistor MH with a predetermined threshold level V_{TH(H)}. When a potential difference between the two nodes crosses the threshold level V_{TH(H)}, the high-side sensor 280 asserts (for example, sets a high level) a high-side detection signal HDET. In the present embodiment, the high-side sensor 280 compares a drain-source voltage V_{DS(H)} of the high-side transistor MH with the threshold level V_{TH(H)} in a turn-on sequence of the high-side transistor MH and asserts the high-side detection signal HDET when V_{DS(H)}<V_{TH(H)}.

The control circuit 210 causes the high-side driver 220 to generate the high voltage V_{BST} when the control signal S_{CTRL} is in the first state φ1, that is, when the control signal S_{CTRL} instructs turning-on of the high-side transistor MH. Then, in response to the assertion of the high-side detection signal HDET, the control circuit 210 changes the driving capability of the high-side driver 220, that is, a rising rate of the gate voltage V_{HG}.

The low-side sensor 290 compares a voltage between the two nodes of the low-side transistor ML with a predetermined threshold level V_{TH(L)}. When a potential difference between the two nodes crosses the threshold level V_{TH(L)}, the low-side sensor 290 asserts a low-side detection signal LDET. In the present embodiment, the low-side sensor 290 compares a drain-source voltage _{VDS(L)} of the low-side transistor ML with the threshold level V_{TH(L)} in a turn-on sequence of the low-side transistor ML and asserts the low-side detection signal LDET when V_{DS(L)}<V_{TH(L)}.

The control circuit 210 causes the low-side driver 260 to generate the high voltage V_{DD} when the control signal S_{CTRL} is in the second state φ2, that is, when the control signal S_{CTRL} instructs turning-on of the low-side transistor ML. Then, in response to the assertion of the low-side detection signal LDET, the control circuit 210 changes the driving capability of the low-side driver 260, that is, a rising rate of the gate voltage V_{LG}.

When the control signal S_{CTRL} is in the first state φ1, that is, when the assertion of the high-side detection signal HDET does not occur within a predetermined time τ_{H} during a turn-on period of the high-side transistor MH, the control circuit 210 determines that abnormality has occurred. Such abnormality may occur due to, for example, a ground fault of the output line 104. When detecting abnormality, the control circuit 210 asserts an error signal ERR. The predetermined time τ_{H} can be set to be longer than the turn-on time of the high-side transistor MH in a normal state. For example, the predetermined time τ_{H} can be set to be 1 to 10 times the turn-on time, and when the turn-on time is 500 ns, the predetermined time τ_{H} can be set to be in a range of 500 ns to 5 μs.

In addition, when the control signal S_{CTRL} is in the second state φ2, that is, when the assertion of the low-side detection signal LDET does not occur within a predetermined time τ_{L} during a turn-on period of the low-side transistor ML, the control circuit 210 determines that abnormality has occurred. Such abnormality may occur due to, for example, a short-circuit fault of the output line 104. When detecting abnormality, the control circuit 210 asserts the error signal ERR.

The control circuit 210 includes a logic circuit 212 and a timer circuit 214. The logic circuit 212 uses the timer circuit 214 to measure the predetermined time τ_{H}, and determines that abnormality has occurred when the high-side detection signal HDET is not asserted during the measurement period. Similarly, the logic circuit 212 uses the timer circuit 214 to measure the predetermined time τ_{L}, and determines that abnormality has occurred when the low-side detection signal LDET is not asserted during the measurement period.

The above is the configuration of the switching circuit 100. Next, operations of the switching circuit 100 will be described.

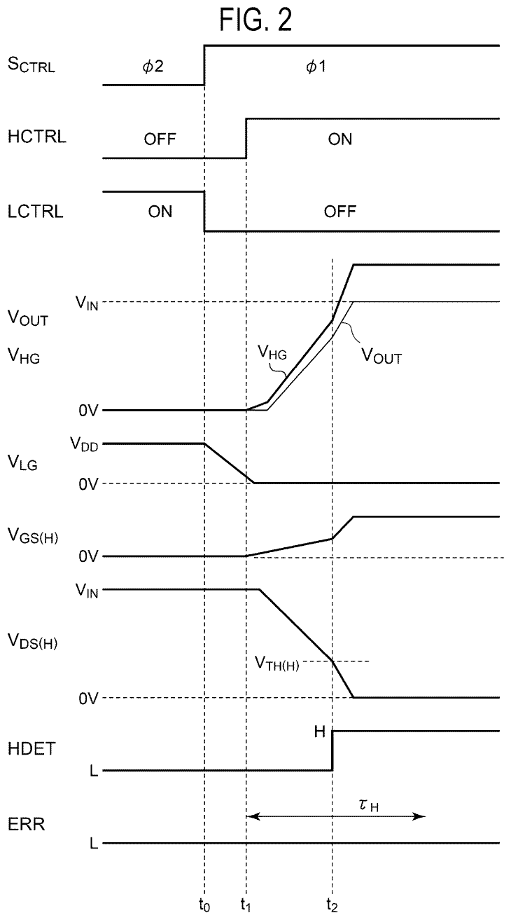

FIG. 2 is a waveform diagram for explaining an operation of the switching circuit 100 of FIG. 1 in a normal state. Here, transition from the low output to the high output will be described.

Before time t₀, the control signal S_{CTRL} indicates the second state φ2, the high-side control signal HCTRL is at a low level, and the low-side control signal LCTRL is at a high level.

At time t₀, the control signal SCTRL changes to the first state φ1. The control circuit 210 switches the low-side control signal LCTRL to a low level. Thus, the low-side driver 260 causes the gate voltage V_{LG} of the low-side transistor ML to be decreased. At time t₁, when a sensor (not shown) detects that the low-side transistor ML is turned off, the control circuit 210 switches the high-side control signal HCTRL to a high level.

When the high-side control signal HCTRL is at the high level, the high-side driver 220 increases the gate voltage V_{HG} of the high-side transistor MH. Initially, the driving capability of the high-side driver 220 is set to be relatively low. When the gate-source voltage V_{GS(H)} of the high-side transistor MH exceeds a gate threshold of MOSFET, the high-side transistor MH is turned on. When the high-side transistor MH is turned on, the output voltage V_{OUT} starts to rise.

As the output voltage V_{OUT} rises, the drain-source voltage V_{DS(H)} of the high-side transistor MH drops. Then, when the drain-source voltage V_{DS(H)} becomes smaller than the threshold level V_{TH(H)} at time t₂, the high-side detection signal HDET is asserted. In response to the assertion of the high-side detection signal HDET, the driving capability of the high-side driver 220 is increased. As a result, a rising rate of the high-side gate voltage V_{HG} increases, and a rising rate of the output voltage V_{OUT} also increases.

The above is the operation of the switching circuit 100 in the normal state. Subsequently, an operation in an abnormal state in which the output line 104 is grounded will be described.

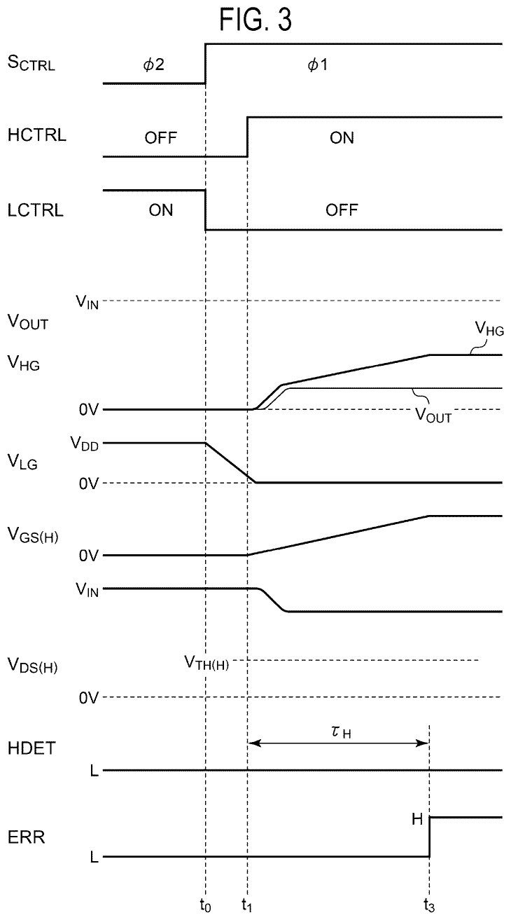

FIG. 3 is a waveform diagram for explaining an operation of the switching circuit 100 of FIG. 1 in an abnormal state. The operation up to time t₁ is the same as in FIG. 2.

At time t₁, the high-side driver 220 increases the gate voltage V_{HG} of the high-side transistor MH. Initially, the driving capability of the high-side driver 220 is set to be relatively low. When the gate-source voltage V_{GS(H)} of the high-side transistor MH exceeds the gate threshold of MOSFET, the high-side transistor MH is turned on. When the high-side transistor MH is turned on, the output voltage V_{OUT} starts to rise.

However, when the output line 104 is grounded, the output voltage V_{OUT} cannot rise and remains near 0 V. Therefore, the drain-source voltage V_{DS(H)} of the high-side transistor MH does not become smaller than the threshold level V_{TH(H)}, and the high-side detection signal HDET continues to be negated.

Since the high-side detection signal HDET is not asserted for the predetermined time TH from time t₁, the control circuit 210 determines that abnormality has occurred, and asserts the error signal ERR.

As described above, the switching circuit 100 can detect a ground fault of the output line 104.

Next, transition from the high output to the low output will be described.

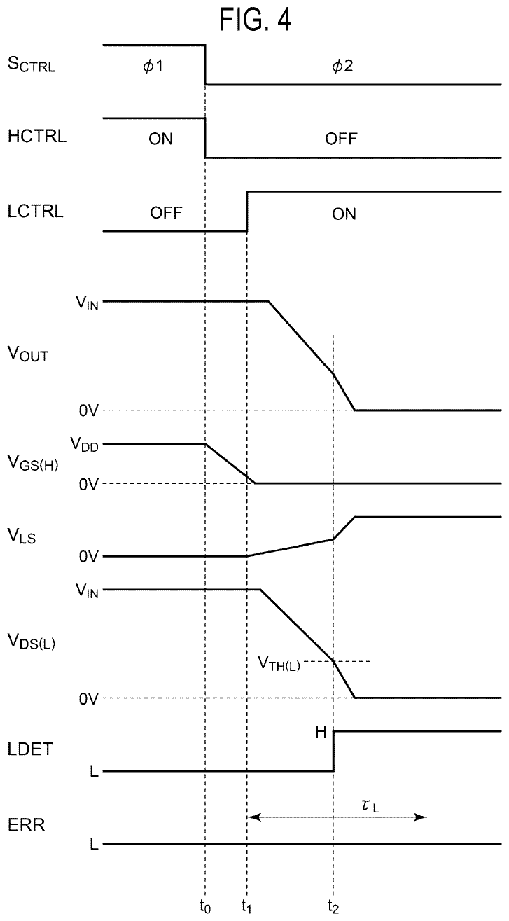

FIG. 4 is a waveform diagram for explaining an operation of the switching circuit 100 of FIG. 1 in a normal state.

Before time t₀, the control signal S_{CTRL} indicates the first state φ1, the high-side control signal HCTRL is a high level, and the low-side control signal LCTRL is at a low level.

At time t₀, the control signal S_{CTRL} changes to the second state φ2. The control circuit 210 switches the high-side control signal HCTRL to a low level. Thus, the high-side driver 220 causes the gate voltage V_{HG} of the high-side transistor MH to be decreased. At time t₁, when a sensor (not shown) detects that the high-side transistor MH is turned off, the control circuit 210 switches the low-side control signal LCTRL to a high level.

When the low-side control signal LCTRL is at the high level, the low-side driver 260 increases the gate voltage V_{LG} of the low-side transistor ML. Initially, the driving capability of the low-side driver 260 is set to be relatively low. When the gate-source voltage V_{GS(L)} of the low-side transistor ML exceeds the gate threshold of MOSFET, the low-side transistor ML is turned on and the output voltage V_{OUT} starts to fall.

As the output voltage V_{OUT} decreases, the drain-source voltage V_{DS(L)} of the low-side transistor ML decreases. Then, when the drain-source voltage V_{DS(L)} becomes smaller than the threshold level V_{TH(L)} at time t₂, the low-side detection signal LDET is asserted. In response to the assertion of the low-side detection signal LDET, the driving capability of the low-side driver 260 is increased. As a result, a rising rate of the low-side gate voltage V_{LG} increases, and a falling rate of the output voltage V_{OUT} also increases.

The above is the operation of the switching circuit 100 in the normal state. Next, an operation in an abnormal state in which the output line 104 is short-circuited will be described.

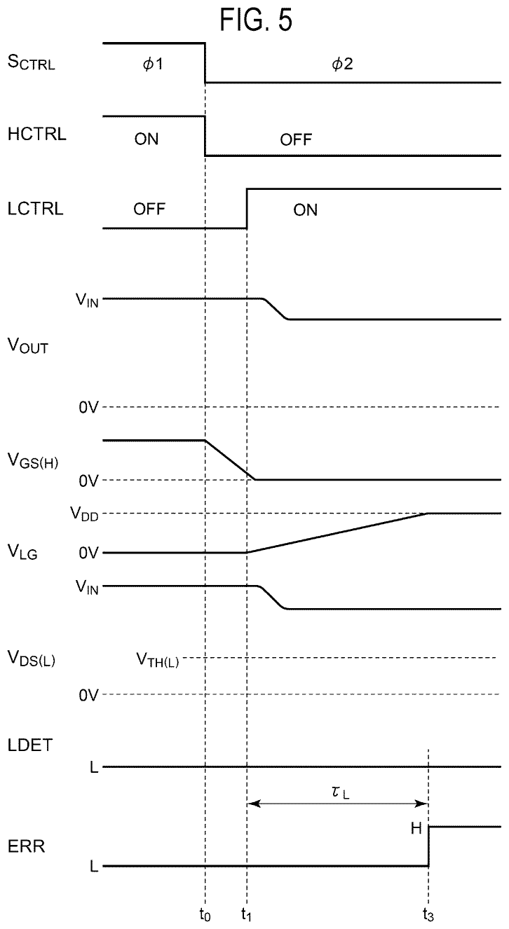

FIG. 5 is a waveform diagram for explaining an operation of the switching circuit 100 of FIG. 1 in an abnormal state. The operation up to time t₁ is the same as in FIG. 4.

At time t₁, the low-side driver 260 increases the gate voltage V_{LG} of the low-side transistor ML. Initially, the driving capability of the low-side driver 260 is set to be relatively low. When the gate-source voltage V_{GS(L)} of the low-side transistor ML exceeds the gate threshold of MOSFET, the low-side transistor ML is turned on, and the output voltage V_{OUT} starts to fall.

However, when the output line 104 is short-circuited, the output voltage V_{OUT} cannot fall and remains near an input voltage V_{IN}. Therefore, the drain-source voltage V_{DS(L)} of the low-side transistor ML does not become smaller than the threshold level V_{TH(L)}, and the low-side detection signal LDET continues to be negated.

Since the low-side detection signal LDET is not asserted for the predetermined time τ_{L} from time t₁, the control circuit 210 determines that abnormality has occurred, and asserts the error signal ERR.

As described above, the switching circuit 100 can detect a short-circuit fault of the output line 104.

Next, a modification of abnormality detection will be described.

When the high-side detection signal HDET, which was asserted once, returns to being negated after the normal transition to the high output state as shown in FIG. 2, the control circuit 210 may determine that abnormality has occurred and assert the error signal ERR.

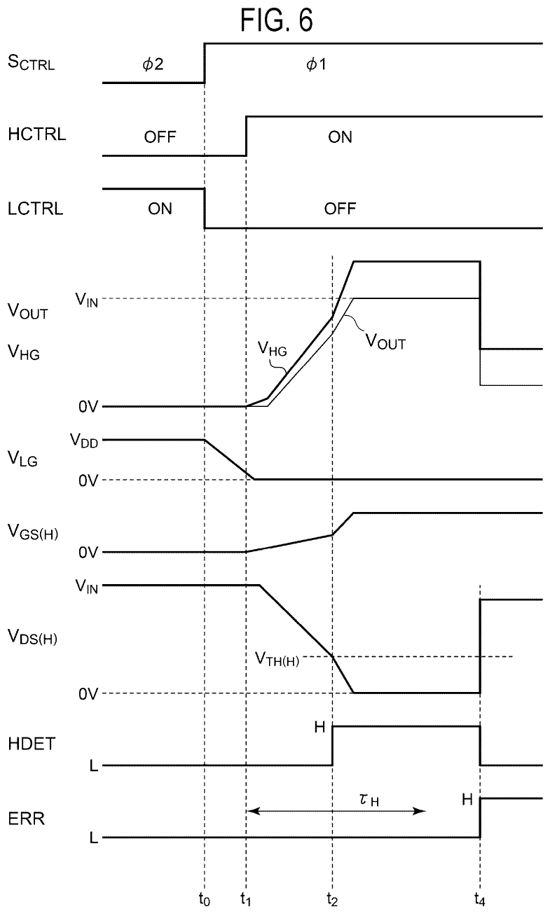

FIG. 6 is a diagram for explaining a modification of abnormality detection in the switching circuit 100 of FIG. 1.

Before time t₄, the waveform diagram is the same as that of FIG. 2. At time t₄, when the output line 104 is grounded, the output voltage V_{OUT} drops to near 0 V. Thus, the drain-source voltage V_{DS(H)} of the high-side transistor MH increases and becomes higher than the threshold level V_{TH(H)}. As a result, the high-side detection signal HDET is negated. The control circuit 210 determines that abnormality has occurred, based on the negation of the high-side detection signal HDET, and asserts the error signal ERR.

When the low-side detection signal LDET, which was asserted once, returns to being negated after the normal transition to the low output state as shown in FIG. 4, the control circuit 210 may determine that abnormality has occurred and assert the error signal ERR.

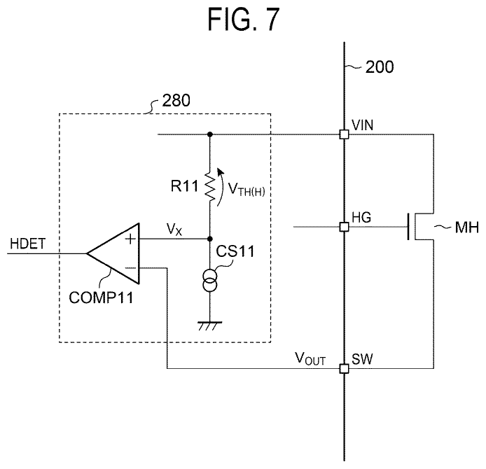

FIG. 7 is a circuit diagram showing an example of a configuration of the high-side sensor 280. The high-side sensor 280 includes a resistor R11, a current source CS11, and a comparator COMP11. The current source CS11 generates a constant current Ic. A voltage drop (R11×Ic) proportional to the constant current Ic is generated in the resistor R11. The comparator COMP11 compares a source voltage of the high-side transistor MH, that is, the output voltage V_{OUT}, with a voltage Vx (=V_{IN}−R11×Ic) at one end of the resistor R11. In other words, the voltage drop (R11×Ic) of the resistor R11 becomes the threshold level V_{TH(H)}.

The configuration of the high-side sensor 280 is not limited to that shown in FIG. 7. For example, instead of the comparator, a MOSFET may be used as a voltage comparison means.

### Modification 1

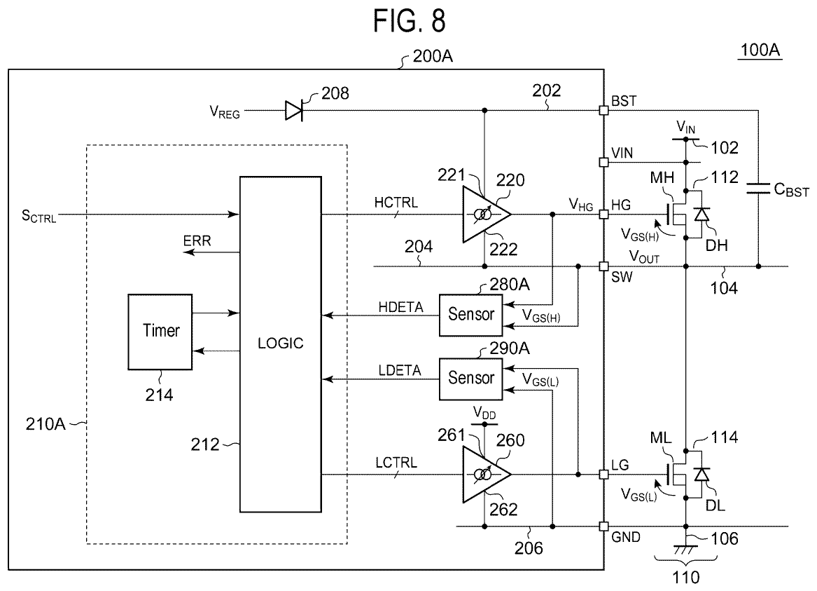

FIG. 8 is a circuit diagram of a switching circuit 100A including a gate driver circuit 200A according to Modification 1. In FIG. 1, the high-side sensor 280 and the low-side sensor 290 monitor gate-drain voltages of power transistors, but in this modification, gate-source voltages are monitored.

A high-side sensor 280A of the gate driver circuit 200A compares the gate-source voltage V_{GS(H)} of the high-side transistor MH with the threshold voltage V_{TH(H)}, and asserts a high-side detection signal HDETA when the two voltages cross. In other words, the high-side detection signal HDETA is asserted when V_{GS(H)}>V_{TH(H)}.

A control circuit 210A sets the driving capability of the high-side driver 220 to be relatively low while the high-side detection signal HDETA is negated. Then, when the high-side detection signal HDETA is asserted, the control circuit 210A sets the driving capability of the high-side driver 220 to be relatively high.

A low-side sensor 290A compares the gate-source voltage V_{GS(L)} of the low-side transistor ML with the threshold voltage V_{TH(L)}, and asserts a low-side detection signal LDETA when the two voltages cross. In other words, the low-side detection signal LDETA is asserted when V_{GS(L)}>V_{TH(L)}.

The control circuit 210A sets the driving capability of the low-side driver 260 to be relatively low while the low-side detection signal LDETA is negated. Then, when the low-side detection signal LDETA is asserted, the control circuit 210A sets the driving capability of the low-side driver 260 to be relatively high.

### Modification 2

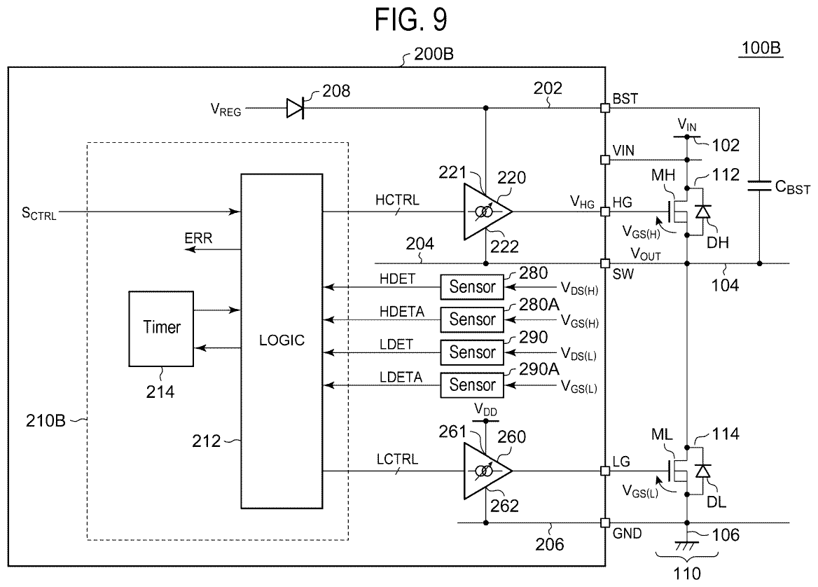

FIG. 9 is a circuit diagram of a switching circuit 100B including a gate driver circuit 200B according to Modification 2. The switching circuit 100B includes high-side sensors 280 and 280A and low-side sensors 290 and 290A, and monitors the gate-drain voltage V_{DS(H)} and gate-source voltage V_{GS(H)} of the high-side transistor MH and the gate-drain voltage V_{DS(L)} and gate-source voltage V_{GS(L)} of the low-side transistor ML.

When turning the high-side transistor MH on, the control circuit 210B uses at least one of the high-side sensors 280 and 280A or the low-side sensors 290 and 290A to switch the driving capability of the high-side driver 220. For example, when the driving capability of the high-side driver 220 can be switched in n steps (n<3) or more, the driving capability of the high-side driver 220 is switched by referring to (n−1) outputs of the high-side sensors 280 and 280A and the low-side sensors 290 and 290A.

In addition, when any of (n−1) detection signals being referred to is not asserted during the predetermined time TH, it can be determined that abnormality has occurred.

When turning the low-side transistor ML on, the control circuit 210B uses at least one of the high-side sensors 280 and 280A or the low-side sensors 290 and 290A to switch the driving capability of the low-side driver 260. For example, when the driving capability of the low-side driver 260 can be switched in n steps (n≥3) or more, the driving capability of the low-side driver 260 is switched by referring to (n−1) outputs of the high-side sensors 280 and 280A and the low-side sensors 290 and 290A.

Next, use of the switching circuit 100 will be described. The switching circuit 100 can be appropriately used in a motor drive circuit.

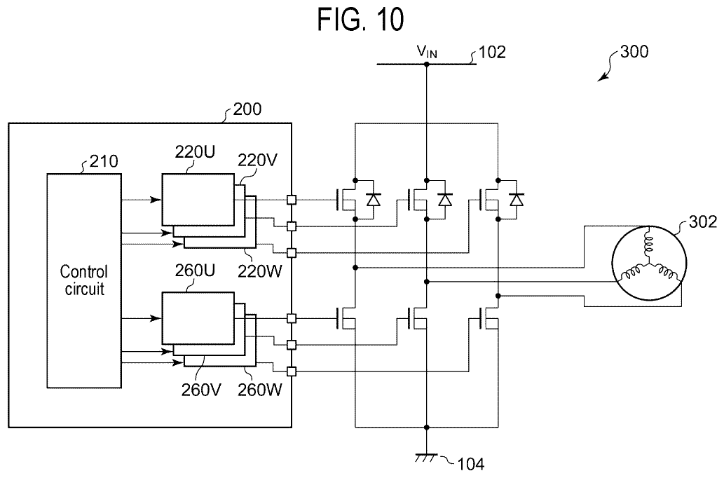

FIG. 10 is a circuit diagram of a motor drive device 300 including the switching circuit 100 according to an embodiment. The motor drive device 300 drives a three-phase motor 302, which is a load, and controls a rotation state.

The motor drive device 300 includes a bridge circuit 110 and a gate driver circuit 200. The bridge circuit 110 is a three-phase inverter and has legs for U, V, and W phases, and the leg for each phase has an upper arm and a lower arm.

The gate driver circuit 200 includes a control circuit 210, high-side drivers 220U to 220W, and low-side drivers 260U to 260W. The control circuit 210 generates a control signal indicating states of six arms constituting the bridge circuit 110, based on a state of the three-phase motor 302 which is the load.

The high-side drivers 220U to 220W are configured with an architecture of the above-described high-side driver 220. In addition, the low-side drivers 260U to 260W are configured with an architecture of the above-described low-side driver 260.

Here, a three-phase motor is used as an example, but the motor may also be a single-phase motor. In this case, the bridge circuit 110 becomes an H-bridge circuit.

Next, the use of the motor drive device 300 will be described. The motor drive device 300 can be used to control a spindle motor of a hard disk or a lens drive motor of an imaging device. Alternatively, the motor drive device 300 can be used to drive a drive motor of a printer head or a paper feed motor. Alternatively, the motor drive device 300 can be used to drive motors of an electric vehicle, a hybrid vehicle, and the like.

The embodiments are merely examples, and it will be understood by those skilled in the art that various modifications can be made in combination of respective components or respective processing processes and that such modifications are also within the scope of the present disclosure. Such modifications will be described below.

### Modifications

The use of the switching circuit 100 is not limited to the motor drive device 300. For example, the switching circuit 100 can be appropriately used in a switching regulator (DC/DC converter), various power conversion devices (inverters and converters), an inverter for lighting a discharge lamp, a digital audio amplifier, and the like. Therefore, the switching circuit 100 can be used in consumer products including electronic apparatuses and home appliances, automobiles and in-vehicle parts, industrial vehicles, and industrial machinery.

The embodiments described using specific terms merely show the principles and applications of the present disclosure, and many modifications and changes in arrangement are permitted in the embodiments as long as they do not deviate from the concept of the present disclosure defined in the claims.

### Supplementary Notes

The following techniques are disclosed in the present disclosure.

### Supplementary Note 1

A gate driver circuit including:
a high-side sensor that asserts a high-side detection signal when a potential difference between two nodes of a high-side transistor constituting an inverter circuit crosses a first threshold level;
a high-side driver configured to be capable of supplying a high voltage or a low voltage between a gate and a source of the high-side transistor and have a controllable driving capability; and
a control circuit that causes the high-side driver to generate the high voltage when a control signal instructs turning-on of the high-side transistor, and changes the driving capability of the high-side driver in response to an assertion of the high-side detection signal,
wherein the control circuit determines that abnormality has occurred when the assertion of the high-side detection signal does not occur within a first predetermined time.

### Supplementary Note 2

The gate driver circuit of Supplementary Note 1, wherein the high-side sensor monitors a drain-source voltage of the high-side transistor.

### Supplementary Note 3

The gate driver circuit of Supplementary Note 1, wherein the high-side sensor monitors a gate-source voltage of the high-side transistor.

### Supplementary Note 4

The gate driver circuit of any one of Supplementary Notes 1 to 3, wherein the first predetermined time is longer than a turn-on time of the high-side transistor in a normal state.

### Supplementary Note 5

The gate driver circuit of any one of Supplementary Notes 1 to 4, wherein the control circuit determines that abnormality has occurred when the high-side detection signal is negated after being asserted once.

### Supplementary Note 6

The gate driver circuit of any one of Supplementary Notes 1 to 5, further including:
a low-side sensor that asserts a low-side detection signal when a potential difference between two nodes of a low-side transistor constituting the inverter circuit crosses a second threshold level; and
a low-side driver configured to be capable of supplying a high voltage or a low voltage between a gate and a source of the low-side transistor and have a controllable driving capability,
wherein the control circuit causes the low-side driver to generate the high voltage when the control signal instructs turning-on of the low-side transistor, and changes the driving capability of the low-side driver in response to an assertion of the low-side detection signal, and wherein the control circuit determines that abnormality has occurred when the assertion of the low-side detection signal does not occur within a second predetermined time.

### Supplementary Note 7

The gate driver circuit of Supplementary Note 6, wherein the control circuit determines that abnormality has occurred when the low-side detection signal is negated after being asserted once.

### Supplementary Note 8

The gate driver circuit of any one of Supplementary Notes 1 to 6, which is integrally integrated on a single semiconductor substrate.

### Supplementary Note 9

A motor drive device including:
an inverter circuit including a high-side transistor and a low-side transistor; and
the gate driver circuit of any one of Supplementary Notes 1 to 8, which drives the high-side transistor and the low-side transistor.

### Supplementary Note 10

An electronic apparatus including:
a motor; and
the motor drive device of Supplementary Note 9, which drives the motor.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gate driver circuit comprising:
a high-side sensor that asserts a high-side detection signal when a potential difference between two nodes of a high-side transistor constituting an inverter circuit crosses a first threshold level;
a high-side driver configured to be capable of supplying a high voltage or a low voltage between a gate and a source of the high-side transistor and have a controllable driving capability; and
a control circuit that causes the high-side driver to generate the high voltage when a control signal instructs turning-on of the high-side transistor, and changes the driving capability of the high-side driver in response to an assertion of the high-side detection signal,
wherein the control circuit determines that abnormality has occurred when the assertion of the high-side detection signal does not occur within a first predetermined time.

2. The gate driver circuit of claim 1, wherein the high-side sensor monitors a drain-source voltage of the high-side transistor.

3. The gate driver circuit of claim 1, wherein the high-side sensor monitors a gate-source voltage of the high-side transistor.

4. The gate driver circuit of claim 1, wherein the first predetermined time is longer than a turn-on time of the high-side transistor in a normal state.

5. The gate driver circuit of claim 1, wherein the control circuit determines that abnormality has occurred when the high-side detection signal is negated after being asserted once.

6. The gate driver circuit of claim 1, further comprising:
a low-side sensor that asserts a low-side detection signal when a potential difference between two nodes of a low-side transistor constituting the inverter circuit crosses a second threshold level; and
a low-side driver configured to be capable of supplying a high voltage or a low voltage between a gate and a source of the low-side transistor and have a controllable driving capability,
wherein the control circuit causes the low-side driver to generate the high voltage when the control signal instructs turning-on of the low-side transistor, and changes the driving capability of the low-side driver in response to an assertion of the low-side detection signal, and
wherein the control circuit determines that abnormality has occurred when the assertion of the low-side detection signal does not occur within a second predetermined time.

7. The gate driver circuit of claim 6, wherein the control circuit determines that abnormality has occurred when the low-side detection signal is negated after being asserted once.

8. The gate driver circuit of claim 1, which is integrally integrated on a single semiconductor substrate.

9. A motor drive device comprising:
an inverter circuit including a high-side transistor and a low-side transistor; and
the gate driver circuit of claim 1, which drives the high-side transistor and the low-side transistor.

10. An electronic apparatus comprising:
a motor; and
the motor drive device of claim 9, which drives the motor.
